(19) United States
(12) Patent Application Publication
(10) Pub. No.: US 2023/0104166 A1
(43) Pub. Date: Apr. 6, 2023

(54) POWER CONVERSION DEVICE

(71) Applicant: FUJI ELECTRIC CO., LTD., Kawasaki-shi (JP)

(72) Inventors: Toshiaki AZUMA, Amagasaki-shi (JP); Shun FUKUCHI, Suzuka-shi (JP)

(21) Appl. No.: 17/892,536

(22) Filed: Aug. 22, 2022

(30) Foreign Application Priority Data
Oct. 1, 2021 (JP) 2021-162826

(51) Int. Cl. H02M 3/00; H02M 3/158; H02M 7/00; H02M 7/537; H02M 1/00; H05K 7/20

(52) U.S. Cl. CPC H02M 3/003; H02M 3/158; H02M 7/003; H02M 7/537; H02M 1/0067; H05K 7/209

(57) ABSTRACT

In this power conversion device, a DC-DC converter substrate on which a DC-DC converter element is mounted is attached to a base portion along the front surface or back surface of the flat plate-shaped base portion.

### CROSS-REFERENCE TO RELATED APPLICATION

The disclosures of Japanese patent application number JP2021-162826, power conversion device, filed on Oct. 1, 2021, and invented by Toshiaki AZUMA and Shun FUKUCHI upon which this patent application is based, are hereby incorporated by reference.

### BACKGROUND OF THE INVENTION

### Field of the Invention

This invention relates to a power conversion device, and more particularly to a power conversion device including a DC-DC converter unit.

### Background Art

A power conversion device including a DC-DC converter unit is known in the related art. Such a power conversion device is disclosed in, for example, International Publication No. 2015/163143.

International Publication No. 2015/163143 discloses a vehicle including an inverter device, a DC-DC converter (DC-DC converter unit), and a flow path forming body. The inverter device includes, for example, a semiconductor module constituting an upper arm and a lower arm. The DC-DC converter includes, for example, a MOSFET and a high-voltage circuit board on which the MOSFET is mounted. The flow path forming body has a flat plate shape with a stepped upper surface. In International Publication No. 2015/163143, the semiconductor module is attached on the upper surface of the flow path forming body. The high-voltage circuit board of the DC-DC converter is attached to the side wall of the flow path forming body.

In International Publication No. 2015/163143, the high-voltage circuit board of the DC-DC converter is attached to the side wall of the flow path forming body. In other words, the high-voltage circuit board is attached so as to be orthogonal to the upper surface of the flat plate-shaped flow path forming body. Accordingly, the high-voltage circuit board is disposed so as to protrude from the upper surface and the lower surface of the flow path forming body. Accordingly, there is a problem that the height of the device including the inverter device and the DC-DC converter increases.

### SUMMARY OF THE INVENTION

The present invention has been made to solve the above problem, and one object of the present invention is to provide a power conversion device in which an increase in height can be suppressed.

In order to achieve the above object, a power conversion device according to one aspect of this invention includes: an inverter unit converting DC power input from a DC power supply into AC power and supplying the power to a load; a DC-DC converter unit converting a voltage of the DC power into a different voltage; and a flat plate-shaped base portion where the inverter unit and the DC-DC converter unit are disposed, in which the inverter unit includes a switching element module converting the DC power into the AC power, the DC-DC converter unit includes a DC-DC converter element and a DC-DC converter substrate where the DC-DC converter element is mounted, the switching element module is attached to the base portion along a front surface or a back surface of the flat plate-shaped base portion, and the DC-DC converter substrate where the DC-DC converter element is mounted is attached to the base portion along the surface or the back surface of the flat plate-shaped base portion.

In the power conversion device according to one aspect of this invention, as described above, the DC-DC converter substrate on which the DC-DC converter element is mounted is attached to the base portion along the front surface or the back surface of the flat plate-shaped base portion. As a result, the DC-DC converter substrate is attached to the base portion along the front surface or the back surface of the flat plate-shaped base portion, and thus an increase in the height of the power conversion device can be suppressed unlike in a case where the DC-DC converter substrate is attached along a direction perpendicular to the front surface or the back surface of the base portion. The “height of the power conversion device” means the height of the power conversion device in a direction perpendicular to the front surface and the back surface of the base portion.

In the power conversion device according to the above aspect, preferably, the switching element module is attached to the base portion along the back surface of the flat plate-shaped base portion, and the DC-DC converter substrate where the DC-DC converter element is mounted is attached to the base portion along the surface of the flat plate-shaped base portion. With such a configuration, the switching element module and the DC-DC converter element are attached to different surfaces, and thus it is possible to suppress the front surface and the back surface of the base portion increasing in size unlike in a case where the switching element module and the DC-DC converter element are attached to the same surface. In other words, it is possible to suppress an increase in the size of the power conversion device in the horizontal direction. The “size of the power conversion device in the horizontal direction” means the size of the power conversion device in a direction along the front surface or the back surface of the base portion.

In the power conversion device according to the above aspect, preferably, the inverter unit includes a first inverter unit and a second inverter unit, the switching element module includes a first switching element module included in the first inverter unit and a second switching element module included in the second inverter unit, and the first switching element module and the second switching element module are attached to the base portion so as to be along the front surface or the back surface of the flat plate-shaped base portion. With such a configuration, the first switching element module and the second switching element module are attached to the base portion along the front surface or the back surface of the base portion, and thus an increase in the height of the power conversion device can be suppressed even in a case where two inverter units are provided.

Preferably, the power conversion device according to the above aspect further includes a boost converter unit disposed on an input side of the inverter unit, boosting the DC power input from the DC power supply, and supplying the power to the inverter unit, in which the boost converter unit is attached to the base portion so along the front surface or the back surface of the flat plate-shaped base portion. With such a configuration, the boost converter unit is also attached to the base portion along the surface or the back surface of the base portion, and thus an increase in the height of the power conversion device can be suppressed even in a case where the boost converter unit is provided.

In this case, preferably, the boost converter unit includes a boost switching element module and a reactor, and the boost switching element module and the reactor are attached to the base portion along the front surface or the back surface of the flat plate-shaped base portion. With such a configuration, the boost switching element module and the reactor are attached to the base portion along the front surface or the back surface of the flat plate-shaped base portion, and thus an increase in the height of the power conversion device can be suppressed unlike in a case where the boost switching element module and the reactor are stacked in the height direction of the power conversion device.

In the power conversion device provided with the reactor, preferably, the switching element module is attached to the base portion along the back surface of the flat plate-shaped base portion, and the DC-DC converter substrate, the reactor, and the boost switching element module are attached to the base portion along the front surface of the flat plate-shaped base portion and adjacent to each other. With such a configuration, the switching element module and the DC-DC converter substrate, the reactor, and the boost switching element module are attached to different surfaces, and thus an increase in the size of the front surface or the back surface of the base portion can be suppressed unlike in a case where the switching element module, the DC-DC converter substrate, the reactor, and the boost switching element module are attached to the same surface without exception.

In the power conversion device according to the above aspect, preferably, the base portion includes a metallic cooling portion main body portion where a cooling flow path is formed and a metallic lid portion covering the cooling flow path of the cooling portion main body portion, and the DC-DC converter substrate is attached to the lid portion. With such a configuration, the DC-DC converter substrate can be more easily cooled by the cooling liquid flowing through the cooling flow path via the lid portion.

In this case, preferably, the DC-DC converter element includes a converter switching element, and the converter switching element is attached so as to come into contact with the lid portion via a heat conductive member on a surface of the DC-DC converter substrate on the lid portion side. With such a configuration, the converter switching element can be easily cooled by the cooling liquid flowing through the cooling flow path. In addition, in a case where the converter switching element is attached to the lid portion by a screw, it is necessary to form the part of the lid portion into which the screw is screwed so as to protrude to the cooling flow path of the cooling portion main body portion, which leads to an increase in the pressure loss of the cooling liquid flowing through the cooling flow path. In this regard, by attaching the converter switching element to the lid portion side surface of the DC-DC converter substrate so as to come into contact with the lid portion via the heat conductive member, it is possible to suppress an increase in the pressure loss of the cooling liquid flowing through the cooling flow path.

In the power conversion device according to the above aspect, preferably, the DC-DC converter element mounted on the DC-DC converter substrate includes a converter switching element, a transformer, a resonance reactor, and a smoothing reactor. With such a configuration, each of the converter switching element, the transformer, the resonance reactor, and the smoothing reactor is disposed along the front surface or the back surface of the flat plate-shaped base portion, and thus it is possible to suppress an increase in the height of the power conversion device including the converter switching element, the transformer, the resonance reactor, and the smoothing reactor.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a power conversion device according to an embodiment.

FIG. 2 is a perspective view of the power conversion device according to the embodiment.

FIG. 3 is a side view of the power conversion device according to the embodiment.

FIG. 4 is an exploded perspective view in which the power conversion device according to the embodiment is viewed from above.

FIG. 5 is an exploded perspective view in which the power conversion device according to the embodiment is viewed from below.

FIG. 6 is a top view of a base portion of the power conversion device according to the embodiment.

FIG. 7 is a bottom view of the base portion of the power conversion device according to the embodiment.

FIG. 8 is a side sectional view of the base portion of the power conversion device according to the embodiment.

### DETAILED DESCRIPTION OF THE INVENTION

Hereinafter, an embodiment of the present invention will be described with reference to the drawings.

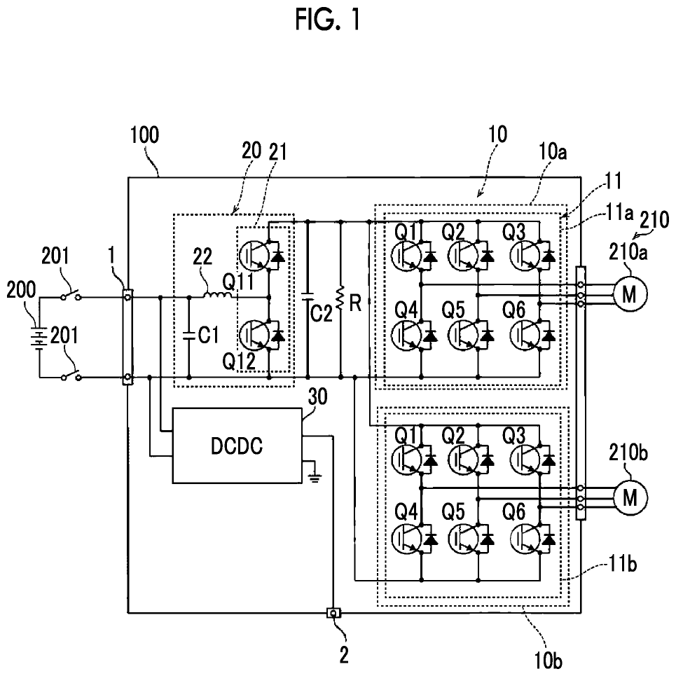

The configuration of a power conversion device 100 according to one embodiment of the present invention will be described with reference to FIGS. 1 to 8. The power conversion device 100 is mounted in, for example, a vehicle.

First, the circuit configuration of the power conversion device 100 will be described with reference to FIG. 1. The power conversion device 100 includes an inverter unit 10. The inverter unit 10 converts DC power input from a DC power supply 200 into AC power and supplies the power to a load 210. The load 210 is, for example, a motor. A switch 201 is provided between the power conversion device 100 and the DC power supply 200.

The inverter unit 10 includes a switching element module 11. The switching element module 11 converts DC power into AC power. In addition, the switching element module 11 includes semiconductor switching elements Q1, Q2, and Q3 constituting an upper arm and semiconductor switching elements Q4, Q5, and Q6 constituting a lower arm.

The inverter unit 10 includes a first inverter unit 10a and a second inverter unit 10b. The switching element module 11 includes a first switching element module 11a included in the first inverter unit 10a and a second switching element module 11b included in the second inverter unit 10b. In addition, the load 210 includes a first load 210a and a second load 210b. The first inverter unit 10a converts DC power input from the DC power supply 200 into AC power and supplies the power to the first load 210a. The second inverter unit 10b converts DC power input from the DC power supply 200 into AC power and supplies the power to the second load 210b.

The power conversion device 100 includes a boost converter unit 20. The boost converter unit 20 is disposed on the input side of the inverter unit 10. The boost converter unit 20 boosts DC power input from the DC power supply 200 and supplies the power to the inverter unit 10. The boost converter unit 20 includes a boost switching element module 21 and a reactor 22. The boost switching element module 21 includes boost switching elements Q11 and Q12. The boost switching elements Q11 and Q12 constitute an upper arm and a lower arm, respectively. In addition, the boost converter unit 20 includes a capacitor C1. The reactor 22 is provided between the positive side of the DC power supply 200 and the connection point between the boost switching element Q11 and the boost switching element Q12. The capacitor C1 is provided in parallel to the boost switching element Q12.

The power conversion device 100 includes a capacitor C2 and a resistor R. The capacitor C2 and the resistor R are provided between the boost converter unit 20 and the inverter unit 10. The capacitor C2 and the resistor R are provided in parallel to each other.

The power conversion device 100 includes a DC-DC converter unit 30. The DC-DC converter unit 30 converts the voltage of DC power into a different voltage. Specifically, the DC-DC converter unit 30 steps down the voltage of DC power input from the DC power supply 200 via a connector 1. In addition, the DC-DC converter unit 30 supplies the stepped-down voltage to an output terminal 2. The DC-DC converter unit 30 is an example of the “DC-DC converter unit” in the claims.

Next, the structure of the power conversion device 100 will be described.

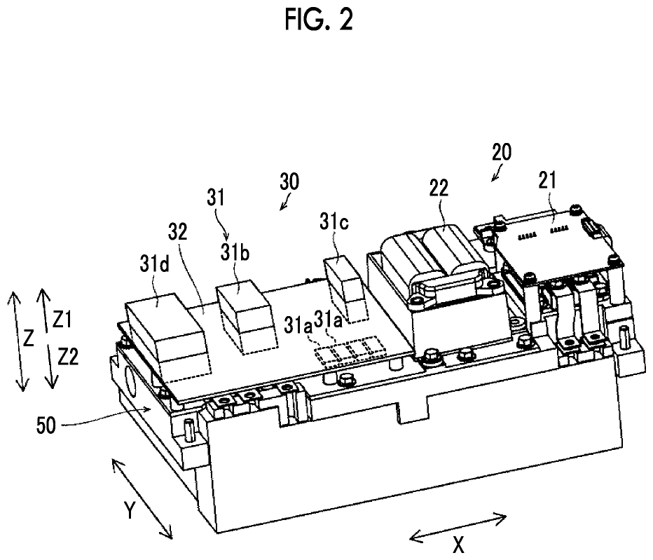

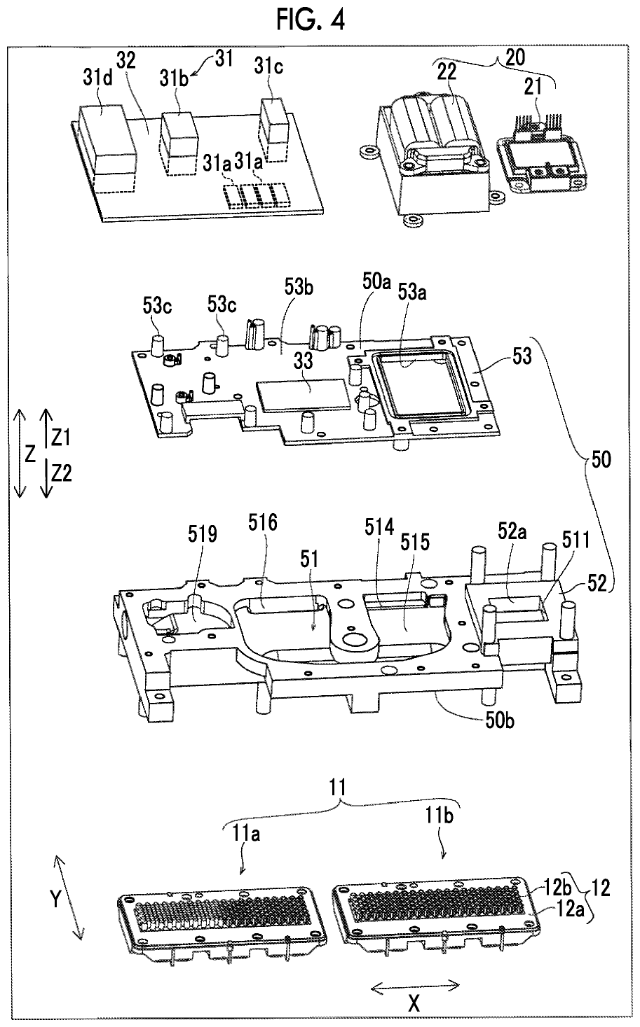

In the present embodiment, as illustrated in FIGS. 2 and 4, the DC-DC converter unit 30 includes a DC-DC converter element 31 and a DC-DC converter substrate 32 on which the DC-DC converter element 31 is mounted. The DC-DC converter substrate 32 has a flat plate shape. The DC-DC converter element 31 mounted on the DC-DC converter substrate 32 includes a converter switching element 31a, a transformer 31b, a resonance reactor 31c, and a smoothing reactor 31d. The converter switching element 31a is provided on the back surface side (Z2 side) of the DC-DC converter substrate 32. The transformer 31b, the resonance reactor 31c, and the smoothing reactor 31d are provided so as to penetrate the DC-DC converter substrate 32.

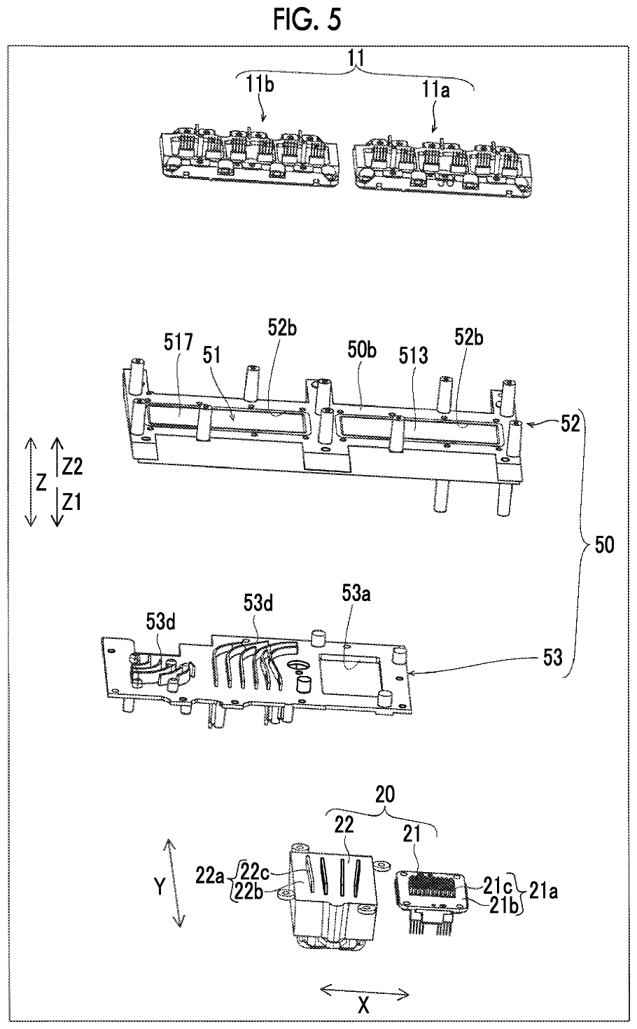

As illustrated in FIG. 5, the semiconductor switching elements Q1 to Q6 (see FIG. 1) are stored in the switching element module 11. The semiconductor switching elements Q1 to Q6 are covered with a housing made of resin or the like. As illustrated in FIG. 4, a lid portion 12 is disposed on a base portion 50 (described later) side (Z1 side) of the switching element module 11. The lid portion 12 is formed of a metal having a relatively high thermal conductivity such as aluminum. The lid portion 12 includes a flat plate-shaped main body portion 12a and a plurality of pillar portions 12b protruding toward the base portion 50. The pillar portion 12b is formed so as to protrude into a cooling flow path 51. The pillar portion 12b has, for example, a prismatic shape. The switching element module 11 has a rectangular shape when viewed from a direction perpendicular to the surface of the switching element module 11.

As illustrated in FIGS. 2 to 5, the power conversion device 100 includes the base portion 50. The base portion 50 has a flat plate shape. On the base portion 50, the inverter unit 10 and the DC-DC converter unit 30 are disposed. In addition, the base portion 50 is formed of a metal having a relatively high thermal conductivity such as aluminum. The base portion 50 has a rectangular shape when viewed from a direction perpendicular to a surface 50a (front side surface (Z1 side surface)) and a back surface 50b (back side surface (Z2 side surface)) of the base portion 50.

As illustrated in FIG. 8, the base portion 50 includes the cooling flow path 51 through which a cooling liquid flows, and the cooling flow path 51 has a front side flow path 51a disposed on the front side and a back side flow path 51b connected to the front side flow path 51a and disposed on the back side.

In addition, the cooling flow path 51 has a connection flow path 51c connecting the front side flow path 51a and the back side flow path 51b in the base portion 50.

In the present embodiment, the switching element module 11 of the inverter unit 10 is attached to the base portion 50 along the surface 50a or the back surface 50b of the flat plate-shaped base portion 50. In addition, the DC-DC converter substrate 32 on which the DC-DC converter element 31 is mounted is attached to the base portion 50 along the surface 50a or the back surface 50b of the flat plate-shaped base portion 50.

Specifically, in the present embodiment, the switching element module 11 is attached to the base portion 50 along the back surface 50b of the flat plate-shaped base portion 50. In addition, the DC-DC converter substrate 32 on which the DC-DC converter element 31 is mounted is attached to the base portion 50 along the surface 50a of the flat plate-shaped base portion 50.

In the present embodiment, the first switching element module 11a and the second switching element module 11b are attached to the base portion 50 along the back surface 50b of the flat plate-shaped base portion 50. Specifically, the first switching element module 11a and the second switching element module 11b are disposed adjacent to each other along the long side direction (X direction) of the first switching element module 11a and the second switching element module 11b. As a result of the arrangement, the width of the base portion 50 in the Y direction can be reduced, and thus the power conversion device 100 can be reduced in size.

Each of the first switching element module 11a and the second switching element module 11b includes an inverter output terminal outputting electric power to the load 210 on the longitudinal side. The inverter output terminal is disposed on at least one side of the longitudinal end portion of the base portion 50.

In the present embodiment, the boost converter unit 20 is attached to the base portion 50 along the surface 50a or the back surface 50b of the flat plate-shaped base portion 50. Specifically, the boost converter unit 20 is attached to the surface 50a of the base portion 50. In addition, the boost converter unit 20 is disposed adjacent to the DC-DC converter unit 30 along the longitudinal direction (X direction) of the flat plate-shaped base portion 50.

In the present embodiment, the boost converter unit 20 includes the boost switching element module 21 and the reactor 22. The boost switching element module 21 and the reactor 22 are attached to the base portion 50 along the surface 50a or the back surface 50b of the flat plate-shaped base portion 50. Specifically, the DC-DC converter substrate 32, the reactor 22, and the boost switching element module 21 are attached to the base portion 50 along the surface 50a of the flat plate-shaped base portion 50 and adjacent to each other. The DC-DC converter substrate 32, the reactor 22, and the boost switching element module 21 are attached to the surface 50a of the base portion 50 in this order.

As illustrated in FIG. 5, a lid portion 21a is disposed on the base portion 50 side (Z2 side) of the boost switching element module 21. The lid portion 21a is formed of a metal having a relatively high thermal conductivity such as aluminum and copper. The lid portion 21a includes a flat plate-shaped main body portion 21b and a plurality of pillar portions 21c protruding toward the base portion 50. The pillar portion 21c is formed so as to protrude into the cooling flow path 51. The pillar portion 21c has, for example, a cylindrical shape. The boost switching element module 21 has a square shape when viewed from a direction perpendicular to the surface of the boost switching element module 21. The lid portion 21a may be provided integrally with the boost switching element module 21. The pillar portion 21c may have a fin function (shape).

A lid portion 22a is disposed on the base portion 50 side (Z2 side) of the reactor 22. The lid portion 22a is formed of a metal having a relatively high thermal conductivity such as aluminum. The lid portion 22a includes a main body portion 22b and a plurality of fins 22c protruding toward the base portion 50. The fin 22c is formed so as to protrude into the cooling flow path 51. The fin 22c is formed so as to extend along the cooling flow path 51.

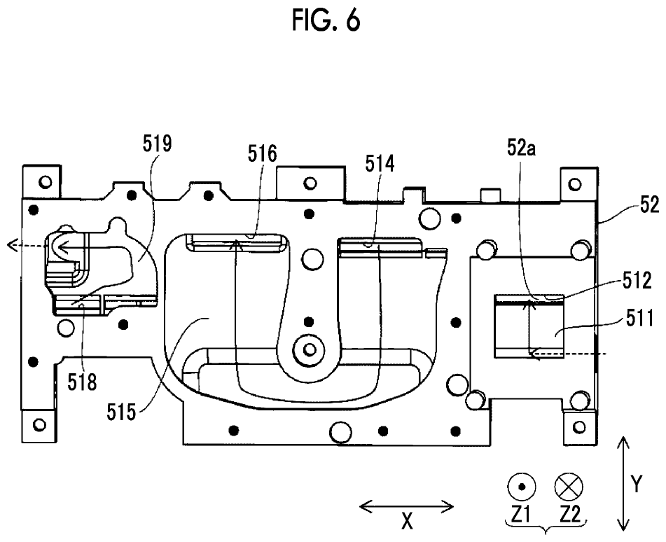

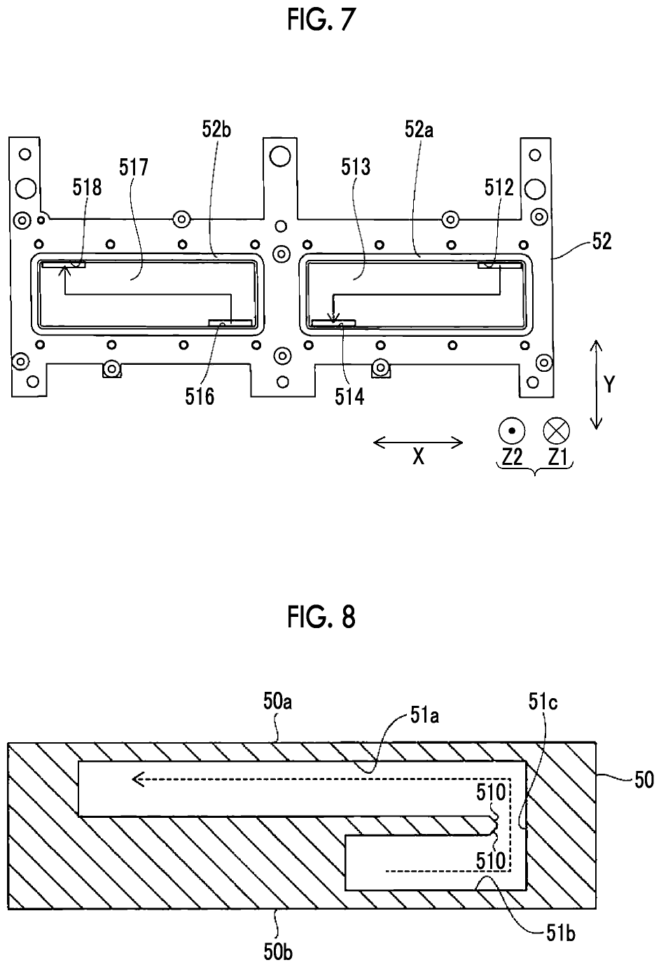

In the present embodiment, as illustrated in FIGS. 4 and 5, the base portion 50 includes a metallic cooling portion main body portion 52 where the cooling flow path 51 is formed, and the lid portions 12, 21a, and 22a and a lid portion 53, which are metallic and form the cooling flow path 51 together with the cooling portion main body portion 52. In addition, the inverter unit 10 and the DCDC converter unit 30 are attached to the lid portions 12 and 53 disposed on the front side and the back side of the base portion 50. Specifically, the DC-DC converter substrate 32 is attached to the lid portion 53. Specifically, the cooling flow path 51 is provided on both the surface 50a and the back surface 50b of the base portion 50 (see FIGS. 6 and 7). The lid portion 53 covers the cooling flow path 51 provided on the surface 50a of the base portion 50. The lid portion 53 has a rectangular shape and a flat plate shape. The DC-DC converter substrate 32 is disposed along a surface 53b of the lid portion 53. The DC-DC converter substrate 32 is attached to a pillar portion 53c provided on the lid portion 53 by, for example, a screw. The lid portion 53 is attached to the cooling portion main body portion 52 by, for example, a screw. As a result, the DC-DC converter substrate 32 and the DC-DC converter element 31 can be easily replaced simply by screw removal. The pillar portion 53c is provided so as not to overlap the cooling flow path 51 in the case of a plan view from the Z1 side of FIG. 4. In this manner, the vibration resistance of the DC-DC converter substrate 32 can be expected to be improved. Alternatively, by providing the pillar portion 53c so as to overlap the cooling flow path 51, a heat dissipation path from the DC-DC converter substrate 32 is formed, and thus heat dissipation improvement can be expected.

The lid portion 53 is formed of a metal having a relatively high thermal conductivity such as aluminum. The lid portion 53 is provided with a fin 53d protruding into the cooling flow path 51. The fin 53d is formed so as to extend along the cooling flow path 51.

In addition, the lid portion 12 covers the cooling flow path 51 provided on the back surface 50b of the base portion 50. Two lid portions 12 are provided. The lid portion 12 has a rectangular shape and a flat plate shape. The first switching element module 11a and the second switching element module 11b are provided integrally with the lid portions 12, respectively. The lid portion 12 may be prepared separately from and attached to the first switching element module 11a and the second switching element module 11b.

In addition, the lid portion 21a covers the cooling flow path 51 provided on the surface 50a of the base portion 50. The lid portion 21a has a rectangular shape and a flat plate shape. The boost switching element module 21 is provided integrally with the lid portion 21a. The lid portion 21a may be prepared separately from and attached to the boost switching element module 21.

In the present embodiment, as illustrated in FIG. 4, the DC-DC converter element 31 includes the converter switching element 31a. The converter switching element 31a is attached so as to come into contact with the lid portion 53 via a heat conductive member 33 on the lid portion 53 side surface (Z2 side surface) of the DC-DC converter substrate 32. In other words, the lid portion 53, the heat conductive member 33, and the converter switching element 31a are stacked in this order. Heat generated from the converter switching element 31a is dissipated to the lid portion 53 via the heat conductive member 33. The heat conductive member 33 is made of, for example, a ceramic sheet.

The DC-DC converter unit 30 includes a capacitor C1 connection terminal connected to the capacitor C1. The capacitor C1 connection terminal is disposed on the other side that is opposite to at least one side of the longitudinal end portion of the base portion 50 where the inverter output terminals of the first switching element module 11a and the second switching element module 11b are disposed. Illustrated in FIG. 2 is a state where the capacitors C1 and C2 are disposed from the left on the paper surface front side in the Y direction below the base portion 50 (Z2 side) and the DCDC converter unit 30 and the capacitor C1 are connected on the paper surface left side in the X direction. By disposing the terminal in this manner, there is no need to worry about the inverter output terminals of the first switching element module 11a and the second switching element module 11b in disposing the capacitor C1, and the disposition of the capacitor C1 on the base portion 50 is facilitated. As a result, the power conversion device 100 can be reduced in size.

In addition, the lid portion 53 is provided with a hole portion 53a. The reactor 22 is disposed so as to cover the hole portion 53a of the lid portion 53. In other words, the reactor 22 is disposed so as to cover the cooling flow path 51. Heat generated from the reactor 22 is dissipated to the cooling liquid flowing through the cooling flow path 51. The reactor 22 is attached to the lid portion 53 by, for example, a screw.

The cooling portion main body portion 52 is provided with a hole portion 52a. The boost switching element module 21 is disposed so as to cover the hole portion 52a of the cooling portion main body portion 52. In other words, the boost switching element module 21 is disposed so as to cover the cooling flow path 51. Heat generated from the boost switching element module 21 is dissipated to the cooling liquid flowing through the cooling flow path 51. The boost switching element module 21 is attached to the cooling portion main body portion 52 by, for example, a screw. The boost switching element module 21 includes a capacitor C2 connection terminal connected to the capacitor C2. The capacitor C2 connection terminal is disposed on the other side that is opposite to at least one side of the longitudinal end portion of the base portion 50 where the inverter output terminals of the first switching element module 11a and the second switching element module 11b are disposed. Illustrated in FIG. 2 is a state where the capacitors C1 and C2 are disposed from the left on the paper surface front side in the Y direction below the base portion 50 (Z2 side) and the boost switching element module 21 and the capacitor C1 are connected on the paper surface right side in the X direction. By disposing the terminal in this manner, there is no need to worry about the inverter output terminals of the first switching element module 11a and the second switching element module 11b in disposing the capacitor C1, and the disposition of the capacitor C1 on the base portion 50 is facilitated. As a result, the power conversion device 100 can be reduced in size. More desirably, the capacitor C1 connection terminal and the capacitor C2 connection terminal are disposed on the same surface side of the longitudinal end portion of the base portion 50.

As illustrated in FIG. 5, the cooling portion main body portion 52 is provided with a pair of hole portions 52b. The first switching element module 11a and the second switching element module 11b are disposed so as to cover the hole portions 52b, respectively. In other words, the first switching element module 11a and the second switching element module 11b are disposed so as to cover the cooling flow path 51. Heat generated from the switching element module 11 is dissipated to the cooling liquid flowing through the cooling flow path 51.

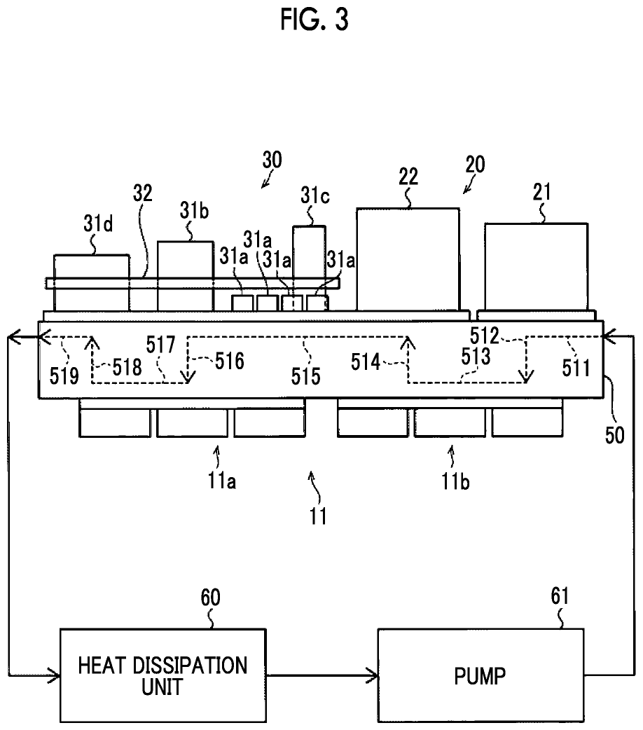

As illustrated in FIG. 3, the cooling flow path 51 is formed such that the front side flow path 51a and the back side flow path 51b are alternately connected and a cooling liquid alternately passes through the front side surface and the back side surface of the base portion 50. Specifically, the cooling flow path 51 includes cooling flow paths 511, 515, and 519 as the front side flow path 51a disposed on the front side (surface 50a side), cooling flow paths 513 and 517 as the back side flow path 51b disposed on the back side (back surface 50b side), and cooling flow paths 512, 514, 516, and 518 as the connection flow path 51c. The cooling flow path 51 is formed such that a cooling fluid flows in from one end side in the longitudinal direction (X direction) of the base portion 50 and the cooling fluid flows out to the other end side.

As for the cooling flow path 51, the cooling flow paths 511, 512, 513, 514, 515, 516, 517, 518, and 519 are connected from upstream toward downstream in this order. In other words, as illustrated in FIGS. 3, 6, and 7, as for the cooling flow path 51, a cooling liquid flows in from the cooling flow path 511 of the front side flow path 51a and the cooling liquid flows out through the cooling flow path 512 of the connection flow path 51c, the cooling flow path 513 of the back side flow path 51b, the cooling flow path 514 of the connection flow path 51c, the cooling flow path 515 of the front side flow path 51a, the cooling flow path 516 of the connection flow path 51c, the cooling flow path 517 of the back side flow path 51b, the cooling flow path 518 of the connection flow path 51c, and the cooling flow path 519 of the front side flow path 51a. The cooling liquid inflow and outflow ports of the cooling flow path 51 may be disposed in the middle of the base portion 50 in the lateral direction. As a result of the disposition, in the power conversion device 100 illustrated in FIG. 2, the positions of the cooling liquid inflow and outflow ports do not change regardless of whether the surface on which the DC-DC converter unit 30 is disposed is disposed on an upper surface or a lower surface in fitting in a customer device, and thus a change in cooling liquid piping disposition is unnecessary on a customer's part.

In addition, the cooling liquid flowing out of the cooling flow path 51 is heat-dissipated by a heat dissipation unit 60 and cooled. In addition, the cooling liquid cooled by the heat dissipation unit 60 is sent by a pump 61 and flows into the cooling flow path 51 again. The heat dissipation unit 60 includes a heat exchanger and is cooled by external air. The heat dissipation unit 60 is, for example, a radiator. The pump 61 may be disposed between the outlet of the cooling flow path 51 and the heat dissipation unit 60 and the cooling liquid that is yet to be heat-dissipated by the heat dissipation unit 60 may be sent by the pump 61. In addition, the cooling liquid is, for example, a liquid such as water and antifreeze.

In addition, as illustrated in FIG. 3, the inverter unit 10 is disposed on the back side of the base portion 50 and is cooled by the cooling liquid flowing through the back side flow path 51b. Specifically, the first switching element module 11a and the second switching element module lib are disposed on the back side of the base portion 50 and are cooled by the cooling liquid flowing through the back side flow path 51b.

In addition, the DC-DC converter unit 30 is disposed on the front side of the base portion 50 and is cooled by the cooling liquid flowing through the front side flow path 51a.

Specifically, the converter switching element 31a, the transformer 31b, the resonance reactor 31c, the smoothing reactor 31d, the boost switching element module 21, and the reactor 22 are disposed on the front side of the base portion 50 and are cooled by the cooling liquid flowing through the front side flow path 51a.

As for the DC-DC converter unit 30, the DC-DC converter element 31 may be disposed on the DC-DC converter substrate 32 in view of the impact of thermal interference from the reactor 22. Specifically, disposing a component that has low heat resistance among the converter switching element 31a, the transformer 31b, the resonance reactor 31c, and the smoothing reactor 31d on the side close to the reactor is avoided.

In addition to the DC-DC converter element 31, components such as a fuse, a capacitor, and a Hall sensor element are mounted on the DC-DC converter unit 30, and heat generated by each of these components is dissipated to the surface 50a of the base portion 50 via a heat dissipation member.

At least a part of the DC-DC converter unit 30 on the reactor 22 side may be covered with a shielding cover so that thermal interference from the reactor 22 is reduced.

In addition, as illustrated in FIG. 8, the connection flow path 51c has a chamfered corner portion. Specifically, chamfered portions 510 are provided at the parts of the connection flow path 51c connected to the front side flow path 51a and the back side flow path 51b. With such a configuration, the pressure loss of the cooling liquid flowing to and from the front side flow path 51a and the back side flow path 51b is suppressed. Further, by providing a flow path adjusting member that is a recessed or protruding portion in the front side flow path 51a near the part of connection to the connection flow path 51c, the pressure loss of the cooling liquid when the flow of the cooling liquid proceeds from the back side flow path 51b to the front side flow path 51a through the connection flow path 51c is suppressed.

In addition, the cooling flow path 51 is formed such that a cooling liquid flows such that the component highest in heat resistance-based priority among the first switching element module 11a, the second switching element module 11b, the converter switching element 31a, the transformer 31b, the resonance reactor 31c, the smoothing reactor 31d, the boost switching element module 21, and the reactor 22 is cooled first. Specifically, as for the cooling flow path 51, a flow path is formed such that the boost switching element module 21 and the reactor 22, which are relatively low in heat resistance, are cooled on the upstream side. Alternatively, the cooling flow path 51 is formed such that a component that has a high cooling priority based on the amount of heat generation among the first switching element module 11a, the second switching element module 11b, the converter switching element 31a, the transformer 31b, the resonance reactor 31c, the smoothing reactor 31d, the boost switching element module 21, and the reactor 22 is disposed on the upstream side.

In addition, the cooling flow path 51 is formed such that a cooling liquid flows such that cooling is performed in the order of the boost switching element module 21, the second switching element module 11b, the reactor 22, the converter switching element 31a, the resonance reactor 31c, the transformer 31b, the first switching element module 11a, and the smoothing reactor 31d.

As illustrated in FIGS. 3, 6, and 7, the boost switching element module 21 is cooled by the cooling liquid flowing through the cooling flow path 511. In addition, the second switching element module 11b is cooled by the cooling liquid flowing through the cooling flow path 513. In addition, the resonance reactor 31c, the converter switching element 31a, and the transformer 31b are cooled by the cooling liquid flowing through the cooling flow path 515. In addition, the first switching element module 11a is cooled by the cooling liquid flowing through the cooling flow path 517. In addition, the smoothing reactor 31d is cooled by the cooling liquid flowing through the cooling flow path 519.

Effects of Present Embodiment

The following effects can be obtained in the present embodiment.

In the present embodiment, as described above, the DC-DC converter substrate 32 on which the DC-DC converter element 31 is mounted is attached to the base portion 50 along the surface 50a or the back surface 50b of the flat plate-shaped base portion 50. As a result, the DC-DC converter substrate 32 is attached to the base portion 50 along the surface 50a or the back surface 50b of the flat plate-shaped base portion 50, and thus an increase in the height of the power conversion device 100 can be suppressed unlike in a case where the DC-DC converter substrate 32 is attached along a direction perpendicular to the surface 50a or the back surface 50b of the base portion 50.

In the present embodiment, as described above, the switching element module 11 is attached to the base portion 50 along the back surface 50b of the flat plate-shaped base portion 50, and the DC-DC converter substrate 32 on which the DC-DC converter element 31 is mounted is attached to the base portion 50 along the surface 50a of the flat plate-shaped base portion 50. As a result, the switching element module 11 and the DC-DC converter element 31 are attached to different surfaces, and thus it is possible to suppress the surface 50a and the back surface 50b of the base portion 50 increasing in size unlike in a case where the switching element module 11 and the DC-DC converter element 31 are attached to the same surface. In other words, it is possible to suppress an increase in the size of the power conversion device 100 in the horizontal direction (direction along the X-Y plane).

In the present embodiment, as described above, the first switching element module 11a and the second switching element module 11b are attached to the base portion 50 along the surface 50a or the back surface 50b of the flat plate-shaped base portion 50. As a result, the first switching element module 11a and the second switching element module 11b are attached to the base portion 50 along the surface 50a or the back surface 50b of the base portion 50, and thus an increase in the height of the power conversion device 100 can be suppressed even in a case where two inverter units 10 are provided.

In the present embodiment, as described above, the boost converter unit 20 is attached to the base portion 50 along the surface 50a or the back surface 50b of the flat plate-shaped base portion 50. As a result, the boost converter unit 20 is also attached to the base portion 50 along the surface 50a or the back surface 50b of the base portion 50, and thus an increase in the height of the power conversion device 100 can be suppressed even in a case where the boost converter unit 20 is provided.

In the present embodiment, as described above, the boost switching element module 21 and the reactor 22 are attached to the base portion 50 along the surface 50a or the back surface 50b of the flat plate-shaped base portion 50. As a result, the boost switching element module 21 and the reactor 22 are attached to the base portion 50 along the surface 50a or the back surface 50b of the flat plate-shaped base portion 50, and thus an increase in the height of the power conversion device 100 can be suppressed unlike in a case where the boost switching element module 21 and the reactor 22 are stacked in the height direction of the power conversion device 100.

In the present embodiment, as described above, the switching element module 11 is attached to the base portion 50 along the back surface 50b of the flat plate-shaped base portion 50, and the DC-DC converter substrate 32, the reactor 22, and the boost switching element module 21 are attached to the base portion 50 along the surface 50a of the flat plate-shaped base portion 50 and adjacent to each other. As a result, the switching element module 11 and the DC-DC converter substrate 32, the reactor 22, and the boost switching element module 21 are attached to different surfaces, and thus an increase in the size of the surface 50a or the back surface 50b of the base portion 50 can be suppressed unlike in a case where the switching element module 11, the DC-DC converter substrate 32, the reactor 22, and the boost switching element module 21 are attached to the same surface without exception.

In the present embodiment, as described above, the base portion 50 includes the metallic cooling portion main body portion 52 where the cooling flow path 51 is formed and the metallic lid portion 53 covering the cooling flow path 51 of the cooling portion main body portion 52. The DC-DC converter substrate 32 is attached to the lid portion 53. As a result, the DC-DC converter substrate 32 can be more easily cooled by the cooling liquid flowing through the cooling flow path 51 via the lid portion 53.

In the present embodiment, as described above, the DC-DC converter element 31 includes the converter switching element 31a, and the converter switching element 31a is attached so as to come into contact with the lid portion 53 via the heat conductive member 33 on the lid portion 53 side surface of the DC-DC converter substrate 32. As a result, the converter switching element 31a can be easily cooled by the cooling liquid flowing through the cooling flow path 51. In addition, in a case where the converter switching element 31a is attached to the lid portion 53 by a screw, it is necessary to form the part of the lid portion 53 into which the screw is screwed so as to protrude to the cooling flow path 51 of the cooling portion main body portion 52, which leads to an increase in the pressure loss of the cooling liquid flowing through the cooling flow path 51. In this regard, by attaching the converter switching element 31a to the lid portion 53 side surface of the DC-DC converter substrate 32 so as to come into contact with the lid portion 53 via the heat conductive member 33, it is possible to suppress an increase in the pressure loss of the cooling liquid flowing through the cooling flow path 51.

In the present embodiment, as described above, the DC-DC converter element 31 mounted on the DC-DC converter substrate 32 includes the converter switching element 31a, the transformer 31b, the resonance reactor 31c, and the smoothing reactor 31d. As a result, each of the converter switching element 31a, the transformer 31b, the resonance reactor 31c, and the smoothing reactor 31d is disposed along the surface 50a or the back surface 50b of the flat plate-shaped base portion 50, and thus it is possible to suppress an increase in the height of the power conversion device 100 including the converter switching element 31a, the transformer 31b, the resonance reactor 31c, and the smoothing reactor 31d.

### MODIFICATION EXAMPLES

The embodiment disclosed above should be considered to be exemplary and unrestrictive in every respect. The scope of the present invention is shown by the claims rather than the description of the embodiment and further includes every change (modification example) within the meaning and scope equivalent to the claims.

In the example shown in the above embodiment, the switching element module 11 is attached to the back surface 50b of the base portion 50 and the DC-DC converter substrate 32 is attached to the surface 50a of the base portion 50. However, the present invention is not limited thereto. For example, the switching element module 11 may be attached to the surface 50a of the base portion 50 and the DC-DC converter substrate 32 may be attached to the back surface 50b of the base portion 50. In addition, both the switching element module 11 and the DC-DC converter substrate 32 may be attached to the surface 50a of the base portion 50. In addition, both the switching element module 11 and the DC-DC converter substrate 32 may be attached to the back surface 50b of the base portion 50.

In the example shown in the above embodiment, both the first switching element module 11a and the second switching element module 11b are attached to the back surface 50b of the base portion 50. However, the present invention is not limited thereto. For example, the first switching element module 11a and the second switching element module 11b may be attached to different surfaces of the base portion 50.

In the example shown in the above embodiment, the boost converter unit 20 is attached to the surface 50a of the base portion 50. However, the present invention is not limited thereto. For example, the boost converter unit 20 may be attached to the back surface 50b of the base portion 50.

In the example shown in the above embodiment, both the boost switching element module 21 and the reactor 22 are attached to the surface 50a of the base portion 50. However, the present invention is not limited thereto. For example, both the boost switching element module 21 and the reactor 22 may be attached to the back surface 50b of the base portion 50. In addition, the boost switching element module 21 and the reactor 22 may be attached to different surfaces of the base portion 50.

In the example shown in the above embodiment, the base portion 50 is separated into the cooling portion main body portion 52 and the lid portion 53. However, the present invention is not limited thereto. For example, the base portion 50 may be integrally formed without separating the cooling portion main body portion 52 and the lid portion 53.

In the example shown in the above embodiment, the DC-DC converter element 31 mounted on the DC-DC converter substrate 32 includes the converter switching element 31a, the transformer 31b, the resonance reactor 31c, and the smoothing reactor 31d. However, the present invention is not limited thereto. For example, the DC-DC converter element 31 mounted on the DC-DC converter substrate 32 may include an element other than these elements.

What is claimed is:

1. A power conversion device, comprising:
an inverter unit converting DC power input from a DC power supply into AC power and supplying the AC power to a load;
a DC-DC converter unit converting a voltage of the DC power into a different voltage; and
a flat plate-shaped base portion where the inverter unit and the DC-DC converter unit are disposed,
wherein the inverter unit includes a switching element module converting the DC power into the AC power,
the DC-DC converter unit includes a DC-DC converter element and a DC-DC converter substrate where the DC-DC converter element is mounted,
the switching element module is attached to the base portion along a front surface or a back surface of the flat plate-shaped base portion, and
the DC-DC converter substrate where the DC-DC converter element is mounted is attached to the base portion along the front surface or the back surface of the flat plate-shaped base portion.

2. The power conversion device according to claim 1,
wherein the switching element module is attached to the base portion along the back surface of the flat plate-shaped base portion, and
the DC-DC converter substrate where the DC-DC converter element is mounted is attached to the base portion along the front surface of the flat plate-shaped base portion.

3. The power conversion device according to claim 1,
wherein the inverter unit includes a first inverter unit and a second inverter unit,
the switching element module includes a first switching element module included in the first inverter unit and a second switching element module included in the second inverter unit, and
the first switching element module and the second switching element module are attached to the base portion along the front surface or the back surface of the flat plate-shaped base portion.

4. The power conversion device according to claim 1, further comprising a boost converter unit disposed on an input side of the inverter unit, boosting the DC power input from the DC power supply, and supplying the power to the inverter unit,
wherein the boost converter unit is attached to the base portion along the front surface or the back surface of the flat plate-shaped base portion.

5. The power conversion device according to claim 4,
wherein the boost converter unit includes a boost switching element module and a reactor, and
the boost switching element module and the reactor are attached to the base portion along the front surface or the back surface of the flat plate-shaped base portion.

6. The power conversion device according to claim 5,
wherein the switching element module is attached to the base portion along the back surface of the flat plate-shaped base portion, and
the DC-DC converter substrate, the reactor, and the boost switching element module are attached to the base portion along the front surface of the flat plate-shaped base portion and adjacent to each other.

7. The power conversion device according to claim 1,
wherein the base portion includes a metallic cooling portion main body portion where a cooling flow path is formed and a metallic lid portion covering the cooling flow path of the cooling portion main body portion, and the DC-DC converter substrate is attached to the lid portion.

8. The power conversion device according to claim 7,
wherein the DC-DC converter element includes a converter switching element, and
the converter switching element is attached so as to come into contact with the lid portion via a heat conductive member on a surface of the DC-DC converter substrate on the lid portion side.

9. The power conversion device according to claim 1,
wherein the DC-DC converter element mounted on the DC-DC converter substrate includes a converter switching element, a transformer, a resonance reactor, and a smoothing reactor.
